(19) United States
(12) Patent Application Publication
(10) Pub. No.: US 2015/0180001 A1
(43) Pub. Date: Jun. 25, 2015

(54) AMORPHOUS IONICALLY-CONDUCTIVE METAL OXIDES, METHOD OF PREPARATION, AND BATTERY

(71) Applicants: Lonnie G. Johnson, Atlanta, GA (US); Davorin Babic, Tempe, AZ (US); Elena N. Krumenaker, Marietta, GA (US); Tedric D. Campbell, Lithia Springs, GA (US); Kieran J. Claffey, Atlanta, GA (US)

(72) Inventors: Lonnie G. Johnson, Atlanta, GA (US); Davorin Babic, Tempe, AZ (US); Elena N. Krumenaker, Marietta, GA (US); Tedric D. Campbell, Lithia Springs, GA (US); Kieran J. Claffey, Atlanta, GA (US)

(73) Assignee: JOHNSON IP HOLDING, LLC, Atlanta, GA (US)

(21) Appl. No.: 14/362,436

(22) PCT Filed: Mar. 2, 2012
(86) PCT No.: PCT/US2012/027545

§ 371 Date: Jun. 3, 2014

Related U.S. Application Data
(60) Provisional application No. 61/566,908, filed on Dec. 5, 2011.

(51) Int. Cl. H01M 2/16; H01M 10/0562; H01M 10/0525; C23C 16/40

(52) U.S. Cl. CPC H01M 2/1686; C23C 16/409; H01M 10/0562; H01M 10/0525; H01M 2300/0071; H01M 2220/30

(57) ABSTRACT

A method for forming an amorphous ionically conductive metal oxide, such as lithium lanthanum zirconium oxide (LLZO), by chemical vapor deposition (CVD), as well as to the ionically conductive material formed by the method, are provided. Such a material may be utilized as a solid electrolyte and/or as a solid separator in an all solid state lithium battery.

### CROSS-REFERENCE TO RELATED APPLICATIONS

This application is a Section 371 application of International Application No. PCT/US2012/027545 filed Mar. 2, 2012, which was published on Jun. 13, 2013 under International Publication No. WO 2013/085557 and which claims priority to U.S. provisional application No. 61/566,908, filed Dec. 5, 2011, the entirety of which are herein incorporated by reference.

### BACKGROUND OF THE INVENTION

This invention relates to a method for forming an amorphous ionically conductive metal oxide, such as lithium lanthanum zirconium oxide (LLZO), by chemical vapor deposition (CVD), as well as to the ionically conductive material formed by the method. Such a material may be utilized as a solid electrolyte and/or a solid separator in an all solid state, or ceramic, battery cell.

A battery cell is a particularly useful article that provides stored electrical energy that can be used to energize a multitude of devices, particularly portable devices that require an electrical power source. A battery cell, which is often referred to in an abbreviated form as a “battery,” is an electrochemical apparatus typically formed of at least one electrolyte (also referred to as an “electrolytic conductor”) disposed between a pair of spaced apart electrodes. Upon completion of a circuit between the electrodes, the battery discharges electrical current as ions flow from a negative electrode (anode) to a positive electrode (cathode).

Rechargeable batteries, also known as secondary batteries, are useful because the energy available for discharge can be replenished by reversing the flow of current between the electrodes such that ions flow from the positive cathode to the negative anode. The type of electrolyte used in rechargeable batteries is important. It is desirable to utilize an electrolyte that promotes optimum transport of ions but that is compatible with the electrode materials and does not adversely affect performance over time or contribute to safety issues. For example, lithium is a desirable anode material because it possesses high energy density. However, the use of lithium as an anode material has presented problems because many materials that are otherwise very effective as electrolytes react adversely with lithium. As another example, many ionically-conductive liquids are effective for ion transport but contribute to diminished performance over time and safety issues.

In the context of the present invention, all solid state batteries are batteries that contain solid electrodes and solid inorganic electrolytes. All solid state lithium and lithium-ion batteries typically contain at least three major components: (1) a cathode, normally made of transition metal oxide powder (such as lithium cobalt oxide, lithium manganese oxide, or lithium manganese nickel cobalt oxide). The cathode material may be sintered to achieve the required electronic conductivity and structural integrity or it may be mixed with carbon or graphite powder to provide electronic conductivity and act as a binder for structural integrity, (2) an anode, made of Li, a Li alloy, or another material capable of intercalating lithium, such as carbon, silicon, lithium titanium oxide, etc., and (3) a solid electrolyte that also serves as a separator between the cathode and anode. Although lithium batteries contain an anode made of pure lithium and lithium ion batteries contain an anode made of lithium-containing material, the terms “lithium battery” and “lithium ion battery” are used interchangeably in this disclosure.

The solid electrolyte is a key element in an all solid state lithium or lithium ion battery. For optimal battery performance, the solid electrolyte should have high Li ion conductivity but negligible electronic conductivity, have long term chemical stability against chemical reactions with metallic lithium, and have high voltage stability (higher than 5.5V). (See, for example, Kotobuki et al; J. Electrochem. Soc. 157, A1076-1079 (2010)). Using a solid electrolyte in a lithium battery eliminates the formation of a solid electrolyte interphase (SEI) layer between Li metal and liquid electrolyte. In liquid electrolyte systems, a SEI film forms during the first electrochemical charge due to the electrochemical reduction of species present in the electrolyte. (See Xu Kang, Chem. Rev, 104, 4303-4417 (2004)). Its formation causes irreversible battery capacity loss associated with the active lithium consumption during the initial SEI layer formation. Additional SEI layer growth in subsequent charge-discharge cycles further lowers the battery capacity by irreversible depletion of the active lithium, also limiting the cycle life of the battery. Accordingly, utilizing a solid electrolyte in an all solid state battery will allow a battery to reach high energy density and utilize metallic lithium anode without detriment to the battery operation. In addition, using an inorganic oxide as an electrolyte prevents loss of oxygen from the cathode materials at high charge voltages, thereby increasing the stability of the cathode and improving the cycle life of the battery.

Different types of materials have been reported as Li-ion conducting materials, including Li₃N, Li-β-alumina, LiSiO₄, Li₃PO₄, LiSICON (lithium superionic conductors, e.g., Li₁₄ZnGe₄O₁₆), lithium phosphorus oxynitride (LiPON), lanthanum lithium titanate (LLTO), lithium titanium phosphate (LTP), lithium aluminum germanium phosphate (LAGP), and garnet-like crystalline structure compounds having the formula Li₅La₃M₂O₁₂ (M=Nb, Ta) or Li₇La₃Zr₂O₁₂. (See Ramzy et al.; Applied Materials & Interfaces 2, 385-390 (2010)). A limitation of the reported compounds is that they have either high ionic conductivity or high electrochemical stability, but not both.

Crystalline Li₇La₃Zr₂O₁₂ (cLLZ) has been recently reported as a new type of garnet-like structure with high lithium-ion conductivity and stability with lithium metal. (See Murugan et al.; Angew. Chem. Int. Ed. 46, 7778-7781 (2007) and Kokal et al.; Solid State Ionics, 185, 42-46 (2011)). This powder material has been synthesized by a solid-state reaction or sol-gel high temperature synthesis and sintered into a pellet for characterization, reportedly having high ionic conductivity in the 10⁻⁴ to 10⁻³ S/cm range. cLLZ has also been reported to be stable with molten lithium and when exposed to air and moisture. Thus, it appears that cLLZ satisfied all the major criteria for a lithium ion solid electrolyte. However, in an attempt to cycle a LiCoO₂/cLLZ/Li cell, the discharge capacity was very low, much lower than expected based on the quantity of LiCoO₂ cathode involved, which was mostly attributed to the high interfacial resistance between the cLLZ pellet and electrodes. A study of the interface between LiCoO₂ and cLLZ revealed the formation of a thick intermediate layer of La₂Coa₄ at the cLLZ/LiCoO₂ interface that was believed to be created by a mutual diffusion of elements during deposition and processing at 700° C. (Kim et al.; J. of Power Sources, 196, 764-767 (2011)). This diffusion layer undergoes further changes during electrochemical charge-discharge cycles and severely limits the performance of the solid state battery. Thus, lowering the deposition temperature can substantially decrease or eliminate the diffusion process and lower the interface resistance.

U.S. Patent Application Publication No. 2011/0053001 of Babic et al. describes a novel lithium ionic conductor material, amorphous lithium lanthanum zirconium oxide (aLLZO), which exhibits high ionic conductivity (˜10⁻³ S/cm), high transport number (˜1), is stable with metallic lithium, and has a high voltage stability window (up to 10V). The aLLZO film taught in the '001 publication is prepared from a sol-gel process, yielding crack-free and precipitate-free sol gel aLLZO films with a smooth surface. However, some pinholes can occur during film nucleation and could propagate without filling in as the layer thickness increases. Since even a single remaining pinhole may result in the failure of a cell, a second continuous layer of solid electrolyte may be applied. For example, a thin layer of lithium phosphorus oxynitride (LiPON) (2 μm) may be used to fill the pores in electrolyte films. However, such films require expensive vacuum equipment for sputtering and are unstable in air (Nimisha et al., Solid State Ionics 185, 47-51 (2011)), making sample handling and transferring during manufacturing very complicated and expensive.

Thus, alternative solid electrolyte materials for high performance all solid state batteries are desirable. Such materials would desirably provide a high level of ion transport, be defect free, and be effective for charge and discharge but not interact adversely with lithium, adversely affect performance over time, or contribute to safety issues.

### BRIEF SUMMARY OF THE INVENTION

A method is provided for synthesizing an amorphous ionically conductive metal oxide having formula M_{w}M′ₓM″_{y}M′″_{z}Cₐ, wherein
M is at least one alkali metal;
M′ is at least one metal selected from the group consisting of lanthanides, barium, strontium, calcium, indium, magnesium, yttrium, scandium, chromium, aluminum, and alkali metals, provided that when M′ is an alkali metal, M′ further contains at least one non-alkali M′ metal;
M″ is at least one metal selected from the group consisting of zirconium, tantalum, niobium, antimony, tin, hafnium, bismuth, tungsten, silicon, selenium, gallium and germanium;
M′ comprises oxygen and optionally at least one element selected from the group consisting of sulfur and halogens; and
w, x, y, and z are positive numbers, including various combinations of integers and fractions or decimals, and “a” may be zero or a positive number. The method comprises:
   (a) introducing a precursor mixture comprising at least one reactant gas and at least one precursor material for each of M, M′, and M″ into a CVD reactor chamber;
   (b) providing a substrate in the CVD chamber; and
   (c) energizing the CVD reactor such that the amorphous ionically conductive metal oxide is deposited on the substrate.

An amorphous ionically conductive metal oxide material according to the invention has formula M_{w}M′ₓM″_{y}M′″_{z}Cₐ, wherein
M is at least one alkali metal;
M′ is at least one metal selected from the group consisting of lanthanides, barium, strontium, calcium, indium, magnesium, yttrium, scandium, chromium, aluminum, and alkali metals, provided that when M′ is an alkali metal, M′ further contains a non-alkali M′ metal;
M″ is at least one metal selected from the group consisting of zirconium, tantalum, niobium, antimony, tin, hafnium, bismuth, tungsten, silicon, selenium, gallium and germanium;
M′ comprises oxygen and optionally at least one element selected from the group consisting of sulfur and halogens; and
w, x, y, and z are positive numbers, including various combinations of integers and fractions or decimals, and “a” may be zero or a positive number. The metal oxide is prepared by a method comprising:
   (a) introducing a precursor mixture comprising at least one reactant gas and at least one precursor material for each of M, M′, and M″ into a CVD reactor chamber;
   (b) providing a substrate in the CVD chamber; and
   (c) energizing the CVD reactor such that the amorphous ionically conductive metal oxide is deposited on the substrate.

A solid state battery according to the invention comprises an anode, a cathode, and a solid electrolyte or solid separator comprising the amorphous ionically conductive metal oxide described previously.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

FIGS. 1(a) and 1(b) are the EIS spectra of an amorphous LLZO CVD film prepared according to one embodiment of the invention;

FIG. 2 is an SEM micrograph of an amorphous LLZO CVD film on glass coated with Al substrate at magnification 9.99K according to an embodiment of the invention;

FIG. 3 is a full EIS spectrum of an amorphous LLZO CVD film with tantalum substitution prepared according to one embodiment of the invention; and

FIG. 4 is a portion of an EIS spectrum emphasizing high frequency real axis intercept of an amorphous LLZO CVD film with tantalum substitution prepared according to one embodiment of the invention.

### DETAILED DESCRIPTION OF THE INVENTION

According to the present invention, a method is provided for synthesizing amorphous ionically conductive metal oxides using chemical vapor deposition. The metal oxides that are produced by the method are also described. These metal oxides may be used as solid electrolytes or solid separators in all solid state batteries.

More specifically, the invention is directed to a CVD method for preparing ionically conductive metal oxides, such as LLZO and lithium carbon lanthanum zirconium oxide (LCLZO). For the purposes of this disclosure, the term “LLZO” may be understood to refer to LLZO and/or LCLZO. The preferred metal oxide according to the invention, LLZO, may also be referred to as lithium lanthanum zirconate or LiLaZrOₓ. Although this invention will be described in detail with respect to LLZO for simplicity, it should be understood that this method is also directed to a whole class of amorphous ionically conductive metal oxides, in which one or more of the constituent elements in LLZO is substituted partly (doped) or completely by another element.

Specifically, lithium may be fully or partially substituted by one or more alkali group metals, such as potassium and sodium. Lanthanum may be fully or partially substituted with one or more metals selected from the group consisting of barium, strontium, calcium, indium, magnesium, yttrium, scandium, chromium, aluminum, alkali metal elements, and lanthanides, such as, but not limited to, cerium and neodymium. If lanthanum is substituted by an alkali metal, it is preferably only partially substituted, such that the compound contains the alkali metal and lanthanum or the alkali metal and at least one other metal selected from barium, strontium, calcium, indium, magnesium, yttrium, scandium, chromium, aluminum, and lanthanides. Zirconium may be fully or partially substituted with one or more metals selected from the group consisting of tantalum, niobium, antimony, tin, hafnium, bismuth, tungsten, silicon, selenium, gallium, and germanium. Finally, oxygen may be partially substituted by sulfur and/or a halogen.

More generally, the amorphous metal oxides prepared by the method of the invention have general formula M_{w}M′ₓM″_{N}M′″_{z}Cₐ, in which M is at least one alkali metal, preferably lithium, M′ is at least one metal selected from the group consisting of lanthanides, barium, strontium, calcium, indium, magnesium, yttrium, scandium, chromium, aluminum, and alkali metals, provided that when M′ is an alkali metal, M′ further contains at least one non-alkali M′ metal, and M′ is preferably lanthanum, M″ is at least one metal selected from the group consisting of zirconium, tantalum, niobium, antimony, tin, hafnium, bismuth, tungsten, silicon, selenium, gallium and germanium and is preferably zirconium or zirconium partially substituted with tantalum and/or niobium, and M′″ comprises oxygen and optionally at least one element selected from the group consisting of sulfur and halogens. In this general formula, w, x, y, and z are positive numbers, including various combinations of integers and fractions or decimals, and “a,” representing the amount of carbon present in the compound, may be zero or a positive number. Thus, metal oxides according to the invention contain at least 4 elements, such as lithium, lanthanum, zirconium, and oxygen in a preferred embodiment. Appropriate elements may be selected based on routine experimentation provided that the resulting compound is amorphous and ionically conductive and may be deposited by CVD.

In chemical vapor deposition, precursor mixture(s) in vapor or mist form are projected into the closed environment of a CVD reactor and caused to be deposited onto a substrate. In one embodiment, the metal oxide material according to the invention is formed or deposited in a thin continuous layer of amorphous inorganic film, and may also be considered to be a coating on a substrate. It is within the scope of the invention to utilize various forms of CVD, including but not limited to metalorganic CVD (MOCVD), atmospheric pressure CVD (APCVD), low-temperature, atmospheric pressure CVD (LTAPCVD), aerosol assisted CVD (AACVD), plasma-enhanced metalorganic CVD (PEMOCVD) and plasma-enhanced CVD (PCVD).

### Method for Preparing Metal Oxides

The method for preparing an amorphous ionically conductive metal oxide involves three essential steps:

(a) introducing a precursor mixture comprising at least one reactant gas and at least one precursor material into a CVD reactor chamber, wherein the precursor material(s) is a source for each component of the amorphous ionically-conductive metal oxide that is not provided by the reactant gas(es);
(b) providing a substrate in the CVD chamber; and
(c) energizing the CVD reactor such that the amorphous ionically conductive metal oxide is deposited on the substrate.
These steps will be described in more detail as follows.

### Introducing Precursor

The first step of the method involves introducing a precursor mixture comprising at least one reactant gas and at least one precursor material into a CVD reactor, preferably in the form of a mist and/or vapor. Appropriate reactant gases include, for example, air, oxygen, and ozone and/or mixtures thereof. Typically, a carrier gas is also employed as a medium for transporting the precursor to the substrate. Exemplary carrier gases include, without limitation, inert gases such as nitrogen and argon. For safety reasons, the reactant gas is typically supplied separately to the carrier gas.

In a preferred embodiment, the precursor is provided as a solution comprising at least one precursor material in an organic solvent. In a preferred embodiment, the solution is a single source reagent solution containing all of the necessary precursor compounds for the metal oxide. For example, a preferred solution for forming LLZO contains precursors of lithium, lanthanum, and zirconium. It is also within the scope of the invention to utilize multiple precursor solutions so that a separate source is provided for each precursor, which react only at the surface of the substrate. The stoichiometry of the final metal oxide material may thus be controlled by adjusting the relative concentrations of the precursor solutions and/or the relative flow from each source.

Appropriate metal precursors include metal alkoxides, metal nitrates, metal β-diketonates, and derivatives thereof. Examples of suitable ligands include acetylacetonate (acac), 2,2,6,6 tetramethyl-3,5 heptadionate (thd), tris(2,2,6,6 tetramethyl-3,5 heptadionato)tetraglyme adduct, etc. Other metal β-diketonates known in the art or to be developed would also be within the scope of the invention. Advantages of these precursor compounds, whether in separate or multiple solutions, are that they are low cost compounds with low toxicity that can be handled in air.

Preferred lithium precursors include lithium alkoxides (such as lithium butoxide), lithium acac, and lithium thd. Preferred lanthanum precursors include lanthanum alkoxides (such as lanthanum methoxyethoxide in methoxyethanol), lanthanum nitrate, lanthanum acac, lanthanum thd, and lanthanum tris(2,2,6,6 tetramethyl-3,5 heptadionato)tetraglyme adduct. Finally, preferred zirconium precursors include zirconium alkoxides (such as zirconium butoxide), zirconium acac, and zirconium thd.

The reagents are preferably soluble in solvents that have appropriate volatility for use in liquid delivery CVD methods. Appropriate solvents should have low viscosity and surface tension and high vapor pressure, as well as high auto ignition point in order to perform deposition at elevated temperatures safely. Preferred solvents include tetrahydrofuran (THF) and alcohols, such as methanol and ethanol.

The solution comprising at least one precursor material may additionally contain one or more additional components, such as surfactants and stabilizers, to make it more readily susceptible to ultrasonic mist formation. Examples of suitable surfactants include, but are not necessarily limited to, nonionic polyoxyethylene surfactants such as Brij 30 and Brij 35. Exemplary stabilizers include, without limitation, acetic acid, and propionic acid.

The concentration of precursor compounds in the reagent solution is not particularly limited, and is preferably about 0.001 M to about 0.2M for each component. For forming LLZO, the ratio of Li:La:Zr preferably ranges from about 7:1:1 to about 7:4:3 regardless of whether the lithium, lanthanum, and zirconium precursors are provided in one solution or in three separate solutions.

When a precursor solution is utilized, it is preferably introduced or provided into a CVD reactor chamber as a vapor or mist. In a preferred embodiment, an ultrasonic piezo element driver (such as one commercially available from Franklin Electric, Oklahoma City, Okla.) is used to create an aerosol mist that is swept into the reaction chamber by a carrier gas, preferably an inert gas such as nitrogen or argon. The reactant gas (air, oxygen, and/or ozone) is preferably introduced to the chamber parallel to the carrier gas to prevent reaction of the precursors before reaching the substrate. It is also within the scope of the invention to utilize a showerhead gas delivery system to improve gas uniformity over the substrate surface. Other methods that are known in the art or to be developed for delivering a mist or vapor of a precursor solution to a CVD reactor are also within the scope of the invention.

It is also within the scope of the invention to utilize a solid precursor rather than a solution of precursor material(s). Appropriate solid precursors include metal thd compounds, for example, which sublime at temperatures of about 150 to 250° C. Thus, when a solid precursor is employed, it is preferably vaporized or sublimed (by heating to above the sublimation temperature) prior to introduction into the CVD chamber.

### Providing a Substrate

The second step of the method involves providing a substrate in the CVD chamber. Appropriate substrates include glass, glass coated with conductive (metal) films (i.e., aluminum or gold), ionically conductive solids that can be used as battery separators (i.e., lithium aluminum germanium phosphate (LAGP), lithium aluminum titanium phosphate (LATP), etc.), polymers (i.e., polyimide and other polymers that are stable at CVD deposition temperatures), and anodes and cathodes for lithium batteries, such as LTO, LiCoO₂ and NCM. It is also within the scope of the invention to utilize a layer of metal oxide (such as LLZO) material, previously formed by a sol-gel process or other film deposition or material synthesis process as the substrate surface upon which the ionically conductive metal oxide synthesized by the process described herein is deposited.

### Energizing the Reactor and Depositing the Metal Oxide

Finally, the method involves energizing the CVD reactor such that the amorphous ionically conductive metal oxide is deposited on the substrate; the precursor vapors pyrolytically decompose and react on the hot substrate to form the metal oxide coating. The substrate temperature should be high enough to cause decomposition of the reagents to deposit the metal oxide on the surface of the substrate, but below the auto ignition point of the solvent and low enough that no damage is caused to the substrate itself. Preferably, the substrate temperature is between about 270° C. and about 350° C.

The CVD reactor may be operated under vacuum or atmospheric pressure (APCVD). Preferably, APCVD is employed because of low equipment cost, the ability to deposit films on large area substrates, and simple process controls. These advantages provide for the ability to inexpensively produce high energy rechargeable all solid state lithium batteries, for example, containing the amorphous metal oxides.

### Preparation of Crystalline Metal Oxides

It is also within the scope of the invention to prepare crystalline ionically conductive metal oxides. Such metal oxides have the general formula M_{w}M′ₓM″_{y}M′″_{z}Cₐ as previously described. A preferred crystalline ionically conductive metal oxide is crystalline LLZO, also referred to as “cLLZ” or “cLLZO.” Such materials have a garnet-type crystal structure. Two different approaches may be employed to prepare the crystalline metal oxides. A first approach involves initially depositing an amorphous ionically conductive metal oxide by CVD as previously described. Subsequently, the amorphous material is annealed by heating to about 720 to about 1300° C. for about one to six hours in air or in oxygen to convert the amorphous material to a crystalline material. Alternatively, the crystalline material may be formed directly by CVD using the method described previously but significantly higher substrate temperatures.

A key advantage of the CVD process lies in the fact that the decomposition of precursors occurs at or near a hot substrate surface, and film growth proceeds through surface reactions of reactive species. Such species can diffuse on the surface of the substrate, leading to more uniform surface coverage and filling small pores or pinholes. Other advantages of CVD methods include rapid growth of high purity, high density materials at temperatures well below their melting point. The method may be used to deposit films of multi-component compounds and may be easily adapted to a wide variety of substrates. Further, the ability to utilize one or a variety of CVD methods will substantially lower the equipment cost and expand the choice of precursor compounds.

The effectiveness of the CVD process depends highly on the properties of the source materials and the delivery technique, for example. Using liquid delivery of precursors in AACVD gives the advantage of wide selection of precursor compounds (low volatile compounds can be used as well) and the accurate control of the composition when depositing mixed compounds.

### Ionically Conductive Metal Oxides and Batteries

The invention also relates to amorphous and crystalline ionically conductive metal oxides, such as LLZO, formed by the CVD process described herein. As explained above, the ionically conductive metal oxides may be expressed as having general formula M_{w}M′ₓM″_{y}M′″_{z}Cₐ. The amorphous metal oxides prepared according to the invention have been shown to exhibit high ionic conductivity of at least about 5E-5 S/cm. Accordingly, such materials may be utilized as solid electrolyte materials which may function as suitable replacements for the flammable organic liquid or polymer electrolytes that are currently used in commercial lithium batteries. Other possible applications for these materials include, without limitation, electrochromic devices, and other lithium-based electrochemical devices.

Thus, among the possible applications of the ionically conductive material according to the invention is in a solid state lithium battery comprising an anode and a cathode separated by a solid electrolyte or solid separator comprising the ionically conductive material. Preferably, the ionically conductive metal oxide is deposited directly on the cathode, although it may also be deposited on another solid electrolyte. Thus, it is also within the scope of the invention to prepare a battery containing a cathode, an anode, and multilayer solid separator, in which at least one of the layers comprises the ionically conductive metal oxide according to the invention. Appropriate cathode and anode materials for lithium solid state batteries and methods for preparing such batteries are well known in the art and need not be described. Presently preferred cathode materials include NCM and LiCoO₂, and presently preferred anode materials include Li, lithium alloys, and other materials that intercalate lithium. However, the invention is not limited to such materials, and other electrode materials known in the art or to be developed for solid state batteries would also be within the scope of the invention.

Although the term “battery” technically may more properly define a combination of two or more cells, it has come to be used popularly to refer to a single cell. Thus the term battery by itself is sometimes for convenience of explanation used herein to refer to what is actually a single cell. The teachings herein that are applicable to a single cell are applicable equally to each cell of a battery containing multiple cells.

All solid state lithium batteries containing the amorphous ionically conductive metal oxide material will be desirable due to high capacity and energy density, battery safety and high temperature stability.

Such batteries will be intrinsically safe and should show no capacity degradation with cycling while supporting very high charge/discharge rate, and will be able to operate without significant loss of performance in the wide temperature range between about −40 and 150° C. Fabricating of a stable continuous layer of an amorphous inorganic electrolyte between cathode and anode will greatly improve yield and eliminate shorts in all-solid-state battery.

Thus, the amorphous ionically conductive metal oxide, such as aLLZO, will be very effective solid electrolytes in rechargeable batteries. These materials will facilitate the transport of ions (particularly lithium ions) very effectively, are compatible with lithium as an anode material, do not diminish in performance over time as with some liquid electrolytes, and do not promote safety problems associated with liquid electrolytes.

This invention will now be described in connection with the following, non-limiting examples.

### EXAMPLES

### Example 1

### Preparation and Analysis of LLZO Film Using APCVD

### LLZO Film Preparation

A precursor solution for LLZO was prepared by dissolving at room temperature 0.5 grams of lithium acetylacetonate, 0.58 grams of lanthanum nitrate La(No₃)₃xH₂O and 0.33 grams of zirconium acetylacetonate in 240 mL of ethanol, commercially available from Strem Chemicals and Sigma Aldrich. The amount of metal precursors corresponds to a molar ratio of lithium to lanthanum to zirconium of 7:2:1. An ultrasonic nebulizer was used to generate an aerosol mist of the precursor solution and a carrier gas (nitrogen) transported the aerosol mist to the substrate. In the aerosol, the liquid droplet size distribution was in the range of 5-20 μm, leading to easy evaporation of the droplets before they reached the substrate surface. A reactant gas (oxygen) was introduced to the deposition chamber separate from the mist. Glass substrates, aluminum foil, and cathodes were used as substrates, which were heated to about 270 to 350° C.

Clear, transparent, smooth, and shiny films were obtained with good adhesion to the substrates. Film thickness depended on precursor concentration, carrier gas flow rate, substrate temperature, and deposition time, and varied between 100 and 1000 nm. Thus, three major requirements for successful film synthesis were established: stable mist formation, full solubility of precursors in a solvent, and high auto ignition point of the solvent in order to perform deposition at or below 350° C. safely.

### Ionic Conductivity Measurements

Ionic conductivity of aLLZO CVD films was measured by electrochemical impedance spectroscopy (EIS) using the high frequency real axis intercept as the lithium ionic resistance of the sample and taking the sample geometry into account. EIS spectra were measured using a Solartron SI 1260 Impedance Analyzer instrument in the frequency range from 32 MHz to 1 Hz.

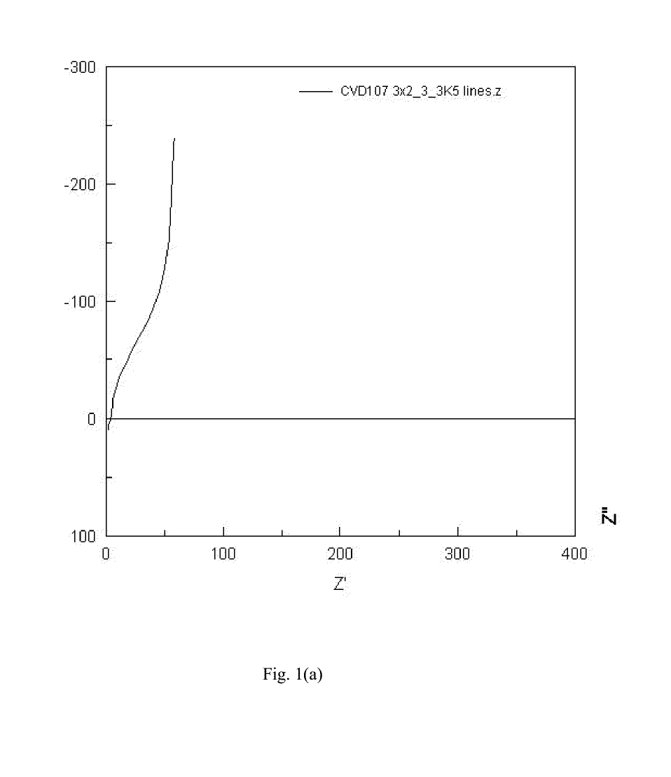

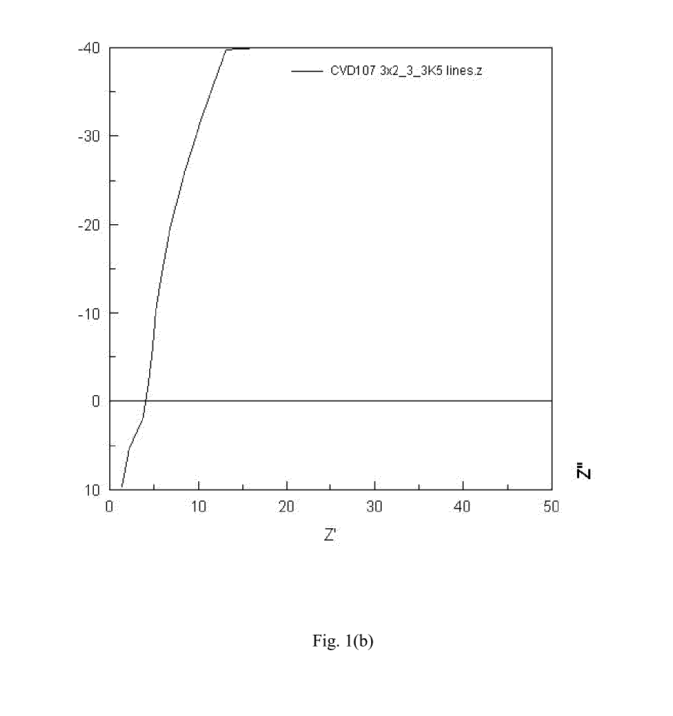

The aLLZO thin films for the EIS measurements were prepared by first sputtering aluminum bars (3 mm wide) on a glass substrate. This was followed by deposition of an aLLZO CVD film as described above. The second contact consisted of gold bars (1 mm wide) sputtered perpendicularly to the aluminum bars on the top of the aLLZO CVD film. FIGS. 1(a) and 1(b) show the EIS spectra of a representative aLLZO CVD film, including full spectrum (FIG. 1(a)) and real axis intercept (FIG. 1(b)).

As shown in FIG. 1(b), the high frequency intercept, which indicates the ionic conductivity of the CVD aLLZO film, extrapolates to about 5 Ohms. Based on the geometry of the sample and the resistance (R) value of the high frequency intercept, the ionic conductivity (σ) of the CVD LLZO was estimated to be 2.5E-4 S/cm. No electronic conductivity was exhibited by these samples, as determined by the shape of the EIS curve.

Other CVD aLLZO samples prepared in a similar manner exhibited ionic conductivities within an order of magnitude of this sample, from about 5E-5 S/cm to about 3E-4 S/cm.

### Elemental Analysis of LLZO Films

The chemical compositions of a typical LLZO film were determined by XPS using an apparatus from Kratos Analytical. Table 1 shows the measured atomic concentration (%) of lithium, lanthanum, zirconium, oxygen, and carbon on the surface of LLZO and as a function of the film depth. The presence of carbon in the films is due to the metal organic precursors used in the synthesis.

TABLE 1
XPS analysis of LLZO CVD film

| Sample | Li 1s | La 3d | Zr 3d | O 1s | C 1s |
|---|---|---|---|---|---|
| LLZO film surface | 15.40 | 10.10 | 7.90 | 52.20 | 14.40 |
| ~6 nm | 13.00 | 11.30 | 9.80 | 54.60 | 11.20 |
| ~12 nm | 17.50 | 11.10 | 8.60 | 48.60 | 14.10 |
| ~18 nm | 16.10 | 10.60 | 8.50 | 48.70 | 16.10 |
| ~24 nm | 4.50 | 12.00 | 10.30 | 56.50 | 16.70 |
| ~30 nm | 5.50 | 13.10 | 10.00 | 56.60 | 14.90 |
| Average in depth | 11.32 | 11.62 | 9.44 | 53.00 | 14.60 |

### Film Morphology

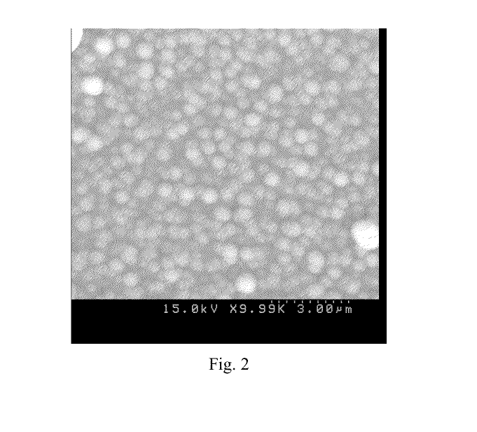

The film morphology of typical LLZO films deposited on glass/Al and aluminum foil substrates was studied using a Hitachi S-4200 scanning electron microscope (SEM). As shown in FIG. 2, the films deposited on glass coated with Al show a fine grained and dense film surface with a grain size of 300-500 nm. This microstructure was smoother for the films deposited on the aluminum foil substrate.

### Example 2

### Preparation and Analysis of Amorphous LLZO by APCVD with Partial Substitution by Tantalum

An amorphous LLZO film with partial tantalum substitution was prepared by mixing 0.53 grams of lithium acetylacetonate (LiAcac), 0.62 grams of hydrated lanthanum nitrate La(NO₃)₃xH₂O (LaNO), 0.28 grams of zirconium acetylacetonate (ZrAcac) and 0.08 grams of tantalum n-butoxide in 240 ml of ethanol solvent to form a precursor solution. All solution components are commercially available from Strem Chemicals, Sigma Aldrich, and Gelest. An ultrasonic nebulizer was used to generate an aerosol mist of the precursor solution and a carrier gas (nitrogen) was used to transport the mist into the deposition chamber and onto the substrate (glass with sputtered Al bars). A reactant gas (oxygen) was introduced to the deposition chamber separately from the mist. The substrate was heated to about 320° C., facilitating decomposition of the precursors and film deposition on the hot substrate. The deposition was performed at atmospheric pressure.

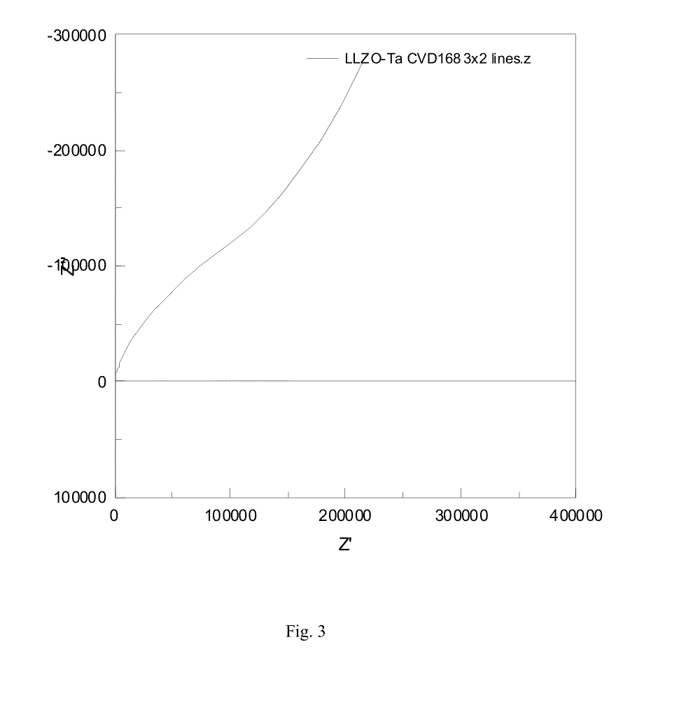

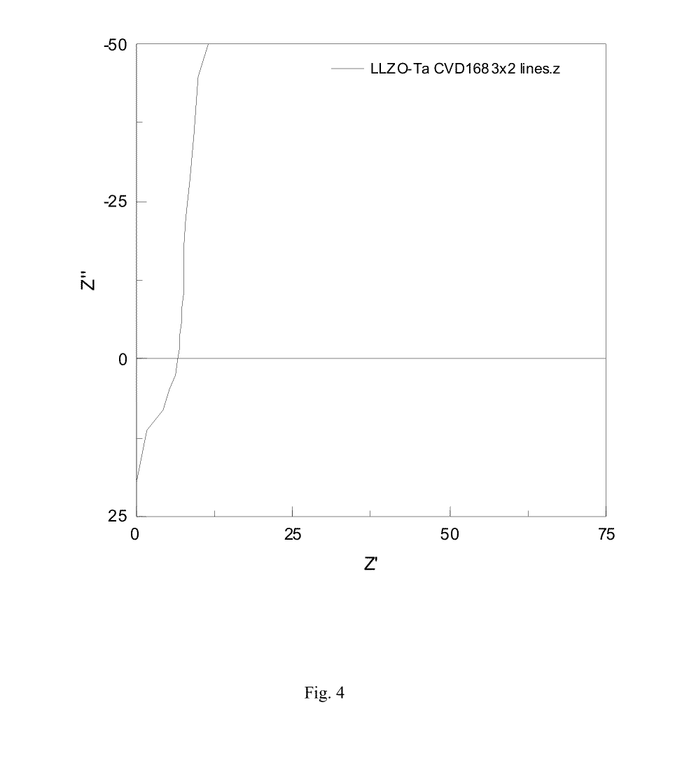

A glass substrate with sputtered Al bars was used to facilitate the measurement of ionic conductivity of the film. Gold bars were sputtered on top of the APCVD deposited film in an orientation perpendicular to the Al bars to form the second electrode for the conductivity measurements. The ionic conductivity was measured by electrochemical impedance spectroscopy (EIS) using a Solartron SI 1260 Impedance Analyzer instrument in the frequency range from 32 MHz to 1 Hz. The ionic conductivity was estimated from the value of the high frequency intercept of the Nyquist plot of the EIS spectra. FIGS. 3 and 4 show the Nyquist plot of the measured EIS spectra; FIG. 3 showing the whole spectrum, indicating pure ionic conduction of the film, and FIG. 4, focusing on the high frequency real axis intercept. The ionic conductivity of the aLLZO film with partial Ta substitution was estimated to be 1.7E-4 S/cm.

### Example 3

### Preparation and Analysis of Amorphous LLZO by APCVD with Partial Substitution by Niobium

A sample of amorphous LLZO with partial substitution by niobium was prepared as described in Example 2, with the exception of the precursor solution. The metal precursor solution contained 0.53 grams of LiAcac, 0.62 grams of LaNO, 0.27 grams of ZrAcac and 0.07 grams of niobium n-butoxide in 240 mL of ethanol. All solution components are commercially available from Strem Chemicals, Sigma Aldrich, and Gelest. The Nyquist plot was similar to the Nyquist plot for Example 2, indicating pure ionic conduction and leading to an ionic conductivity estimate of 6.8E-4 S/cm.

### Example 4

### Preparation and Analysis of Amorphous LLZO by APCVD with Partial Substitution by Barium (a)

A sample of amorphous LLZO with partial substitution by barium was prepared as described in Example 2, with the exception of the precursor solution. The metal precursor solution contained 0.55 grams of LiAcac, 0.54 grams of LaNO, 0.36 grams of ZrAcac and 0.07 grams of barium acetylacetonate in 240 mL ethanol. All solution components are commercially available from Strem Chemicals, Sigma Aldrich, and Gelest. The Nyquist plot was similar to the Nyquist plot for Example 2, indicating pure ionic conduction and leading to an ionic conductivity estimate of 8.6E-5 S/cm.

### Example 5

### Preparation and Analysis of Amorphous LLZO by APCVD with Partial Substitution by Barium (b)

A second sample of amorphous LLZO with partial substitution by barium was prepared as described in Example 2, with the exception of the precursor solution. The metal precursor solution contained 0.55 grams of LiAcac, 0.55 grams of LaNO, 0.36 grams of ZrAcac and 0.28 grams of barium methoxypropoxide in methoxypropanol, all dissolved in 240 ml of ethanol. All solution components are commercially available from Strem Chemicals, Sigma Aldrich, and Gelest. The Nyquist plot was similar to the Nyquist plot for Example 2, indicating pure ionic conduction and leading to an ionic conductivity estimate of 2.9E-4 S/cm.

### Example 6

### Preparation and Analysis of Amorphous LLZO by APCVD with Partial Substitution by Aluminum

A sample of amorphous LLZO with partial substitution by aluminum was prepared as described in Example 6, with the exception of the precursor solution. The metal precursor solution contained 0.51 grams of LiAcac, 0.60 grams of LaNO, 0.34 grams of ZrAcac and 0.05 grams of aluminum t-butoxide in 240 mL of ethanol. All solution components are commercially available from Strem Chemicals, Sigma Aldrich, and Gelest. The Nyquist plot was similar to the Nyquist plot for Example 2, indicating pure ionic conduction and leading to an ionic conductivity estimate of 2.4E-4 S/cm.

### Example 7

### Preparation and Analysis of Amorphous LLZO by APCVD with Partial Substitution by Silicon

A sample of amorphous LLZO with partial substitution by silicon was prepared as described in Example 2, with the exception of the precursor solution. The metal precursor solution contained 0.52 grams of LiAcac, 0.61 grams of LaNO, 0.34 grams of ZrAcac and 0.07 grams of tetraethoxysilane (TEOS) in 240 ml ethanol. All solution components are commercially available from Strem Chemicals, Sigma Aldrich, and Gelest. The Nyquist plot was similar to the Nyquist plot for Example 2, indicating pure ionic conduction and leading to an ionic conductivity estimate of 1.3E-4 S/cm.

It can thus be seen that amorphous ionically conductive metal oxide materials containing a variety of different elements may be prepared by the chemical vapor deposition according to the invention. Further, the same method is applicable to a wide variety of elemental substitutions, merely requiring modification in the precursor solution and the substrate deposition temperature, if necessary.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A method for synthesizing an amorphous ionically conductive metal oxide having formula M_{w}M′ₓM″_{y}M′″_{z}Cₐ,
wherein M is at least one alkali metal;
M′ is at least one metal selected from the group consisting of lanthanides, barium, strontium, calcium, indium, magnesium, yttrium, scandium, chromium, aluminum, and alkali metals, provided that when M′ is an alkali metal, M′ further contains at least one non-alkali M′ metal;
M″ is at least one metal selected from the group consisting of zirconium, tantalum, niobium, antimony, tin, hafnium, bismuth, tungsten, silicon, selenium, gallium and germanium;
M′″ comprises oxygen and optionally at least one element selected from the group consisting of sulfur and halogens; and
w, x, y, and z are positive numbers, including various combinations of integers and fractions or decimals, and “a” may be zero or a positive number;
the method comprising:
(a) introducing a precursor mixture comprising at least one reactant gas and at least one precursor material for each of M, M′, and M″ into a CVD reactor chamber;
(b) providing a substrate in the CVD chamber; and
(c) energizing the CVD reactor such that the amorphous ionically conductive metal oxide is deposited on the substrate.

2. The method of claim 1, wherein the ionically conductive metal oxide comprises at least one of lithium lanthanum zirconium oxide and lithium carbon lanthanum zirconium oxide.

3. The method of claim 1, wherein the precursor is a solid, and wherein step (a) comprises subliming the solid to form a vapor and introducing the vapor into the CVD reactor chamber.

4. The method of claim 1, wherein the precursor comprises a solution comprising the at least one precursor material, and wherein step (a) comprises introducing the solution in a mist or vapor state into the CVD reactor chamber.

5. The method according to claim 1, wherein the substrate comprises a battery electrode or an ionically conductive battery separator.

6. The method of claim 2, wherein the precursor comprises a solution comprising lithium acetylacetonate, lanthanum nitrate, and zirconium acetylacetonate.

7. The method of claim 6, wherein step (a) comprises introducing the solution in a mist or vapor state into the CVD reactor chamber.

8. The method of claim 4, wherein the at least one precursor material is selected from the group consisting of a metal alkoxide, a metal nitrate, a metal β-diketonate, and derivatives thereof.

9. The method of claim 8, wherein the at least one precursor material comprises a metal β-diketonate comprising a ligand selected from the group consisting of acetylacetonate; 2,2,6,6 tetramethyl-3,5 heptadionate, and tris(2,2,6,6 tetramethyl-3,5 heptadionato)tetraglyme adduct.

10. The method of claim 1, wherein M is lithium, M′ is lanthanum, M″ is selected from the group consisting of zirconium, tantalum, and niobium, and M″ comprises oxygen.

11. The method of claim 1, wherein the substrate is heated to a temperature of about 270 to about 350° C.

12. The method of claim 1, wherein the method is performed at atmospheric pressure.

13. The method of claim 1, wherein the metal oxide has an ionic conductivity of at least about 5E-5 S/cm.

14. An amorphous ionically conductive metal oxide film having formula
M_{w}M′ₓM″_{y}M′″_{z}Cₐ,
wherein M is at least one alkali metal;
M′ is at least one metal selected from the group consisting of lanthanides, barium, strontium, calcium, indium, magnesium, yttrium, scandium, chromium, aluminum, and alkali metals, provided that when M′ is an alkali metal, M′ further contains at least one non-alkali M′ metal;
M″ is at least one metal selected from the group consisting of zirconium, tantalum, niobium, antimony, tin, hafnium, bismuth, tungsten, silicon, selenium, gallium and germanium;
M′″ comprises oxygen and optionally at least one element selected from the group consisting of sulfur and halogens; and
w, x, y, and z are positive numbers, including various combinations of integers and fractions or decimals, and a may be zero or a positive number;
wherein the metal oxide is prepared by a method comprising:
(a) introducing a precursor mixture comprising at least one reactant gas and at least one precursor material for each of M, M′, and M″ into a CVD reactor chamber;
(b) providing a substrate in the CVD chamber; and
(c) energizing the CVD reactor such that the amorphous ionically conductive metal oxide is deposited on the substrate.

15. The metal oxide according to claim 14, wherein M is lithium, M′ is lanthanum, M″ is selected from the group consisting of zirconium, tantalum, and niobium, and M″ comprises oxygen.

16. The metal oxide according to claim 14, wherein the ionically conductive metal oxide comprises at least one of lithium lanthanum zirconium oxide and lithium carbon lanthanum zirconium oxide.

17. The metal oxide according to claim 14, wherein the metal oxide has an ionic conductivity of at least about 5E-5 S/cm.

18. A solid state lithium battery comprising a cathode, an anode, and at least one solid electrolyte or solid separator comprising the amorphous ionically conductive metal oxide according to claim 14.

19. The battery according to claim 18, wherein the amorphous ionically conductive metal oxide comprises lithium lanthanum zirconium oxide.

20. The battery according to claim 18, wherein the battery comprises a solid separator, the solid separator comprises at least two layers, and wherein at least one of the layers comprises the amorphous ionically conductive metal oxide.
